(19) United States
(12) Patent Application Publication
(10) Pub. No.: US 2023/0158918 A1
(43) Pub. Date: May 25, 2023

(54) METHODS AND SYSTEMS OF ELECTRIC VEHICLE CHARGING MANAGEMENT FOR COMMUNITY WITH ENERGY MONITORING

(71) Applicant: Noodoe Corporation, Taipei City (TW)

(72) Inventors: John C. WANG, Taipei City (TW); Yi-An HOU, Taipei City (TW)

(21) Appl. No.: 17/896,322

(22) Filed: Aug. 26, 2022

(30) Foreign Application Priority Data
Nov. 25, 2021 (TW) 110144054

(51) Int. Cl. B60L 53/67; G06Q 50/06; H02J 3/14; G01R 22/06; B60L 53/30; B60L 53/63

(52) U.S. Cl. CPC B60L 53/67; G06Q 50/06; H02J 3/144; G01R 22/063; B60L 53/305; B60L 53/63

(57) ABSTRACT

Methods and systems of electric vehicle charging management for community with energy monitoring are provided, which are suitable for a community including a plurality of dwellings, and each dwelling has an electric vehicle charging station connected to a server through a network. First, a current transformer is used to measure the main power lines of the community to obtain a current consumption of the community, where the main power line is tapped into a plurality of auxiliary power lines to provide electricity for each of the dwellings. The server determines whether the current consumption of the community meets a predetermined condition of the community, and if so, the server executes at least one energy management scheme, wherein the energy management scheme records a power distribution logic, which is used to control the charging operation of the electric vehicle charging station corresponding to the respective dwelling via the network.

### BACKGROUND OF THE INVENTION

### Field of the Invention

The disclosure relates generally to charging management methods and systems for electric vehicles, and, more particularly to methods and systems for monitoring the overall electricity consumption of a community in order to provide charging for electric vehicles while maintaining a balanced electricity supply to the community.

### Description of the Related Art

Recently, with the rising awareness of environmental protection and electric vehicle technology advances, the development of electric vehicles powered by electrical energy to replace traditional vehicles powered by fossil fuels has gradually become an important goal in the automotive field, thus making electric vehicles become more and more popular. In order to increase the range and willingness to use electric vehicles, many countries or cities have begun to set up charging stations in public places to provide electricity to electric vehicles, and have also begun to plan the deployment of a large number of charging stations in urban areas or scenic areas, so as to make the charging of electric vehicles more convenient.

Generally, the power equipment in the most field has already been constructed. To update the power equipment, such as the capacity of the electric panel, it is expensive and the construction time is long. Often, the number of charging stations that can be installed in a single charging field is limited by the existing maximum load capacity of the field. Therefore, in the case of limited charging stations, the drivers of electric vehicles may have to wait since the charging station may be in use, or need to find other nearby charging stations for charging operations, which causes inconvenience in use, and drives the willingness to adopt electric vehicles.

On the other hand, the charging situation of electric vehicles in a centralized dwelling, such as a community, will be more complicated than that in a typical dwelling. Each dwelling in a community has its own power consumption limit of, such as 75 amps. If an electric vehicle charging station is added to a dwelling, it is possible that the overall power consumption of the dwelling will exceed the original power consumption design. Additionally, the entire community has its own original design limit for power consumption. Some builders may underestimate the overall dwelling power consumption and downsize the community's electrical infrastructure to save costs. As a result, if a large number of dwellings are equipped with electric vehicle charging stations and a large amount of electricity is required, there is a risk that the community's electrical facilities will not be able to handle the overall dwelling power consumption. Therefore, there is an urgent need for the industry to reduce the difficulty of setting up and managing electric vehicle charging stations in the community, while meeting the charging needs of different households.

### BRIEF SUMMARY OF THE INVENTION

In an embodiment of a method of electric vehicle charging management for community with energy monitoring, which is suitable for a community including a plurality of dwellings, and each dwelling has an electric vehicle charging station connected to a server through a network, a current transformer is first used to measure the main power lines of the community to obtain a current consumption of the community, wherein the main power line is tapped into a plurality of auxiliary power lines to provide electricity for each of the dwellings. The server determines whether the current consumption of the community meets a predetermined condition of the community, and if so, the server executes at least one energy management scheme, wherein the energy management scheme records a power distribution logic, which is used to control the charging operation of the electric vehicle charging station corresponding to the respective dwelling via the network.

An embodiment of a system of electric vehicle charging management for community with energy monitoring, which is suitable for a community including a plurality of dwellings, comprises a plurality of electric vehicle charging stations, a current transformer, and a server. Each electric vehicle charging station corresponds to one of the dwellings and has a network connection capability, and connects to the server. The current transformer measures main power lines of the community to obtain a current consumption of the community and transmits the current consumption of the community to the server via a network, wherein the main power line is tapped into a plurality of auxiliary power lines to provide electricity for each of the dwellings. The server determines whether the current consumption of the community meets a predetermined condition of the community. When the current consumption of the community meets the predetermined condition of the community, the server executes at least one energy management scheme, wherein the energy management scheme records a power distribution logic, which is used to control the charging operation of the electric vehicle charging station corresponding to the respective dwelling via the network.

In some embodiments, the server determines whether the current consumption of the community meets the predetermined condition of the community by determining whether the current consumption of the community is greater than a predetermined upper limit value determined by a maximum current amount defined by the corresponding community and a power company. When the current consumption of the community is greater than the predetermined upper limit value, it is determined that the current consumption of the community meets the predetermined condition of the community.

In some embodiments, the predetermined upper limit value includes a plurality of sub-limit values and when the current consumption of the community is greater than any of the sub-limit values, the energy management scheme executed by the server is different.

In some embodiments, the server determines whether the current consumption of the community meets the predetermined condition of the community by determining whether a phase difference between a first line current and a second line current within the current consumption of the community is greater than a predetermined difference. When the phase difference is greater than the predetermined difference, it is determined that the current consumption of the community meets the predetermined condition of the community.

In some embodiments, at least one of the auxiliary power lines of the main power line is used to provide electricity for at least one public equipment in the community. The at least one energy management scheme executed by the server preferentially controls the power consumption of the at least one public equipment when the current consumption of the community meets the predetermined condition of the community.

In some embodiments, the server obtains charging information of a charging operation from each electric vehicle charging station, wherein the charging information includes a charging start time for the charging operation, a charging amount, or a remaining battery amount corresponding to an electric vehicle. The server executes the at least one energy management scheme based on the charging information of the charging operation corresponding to each electric vehicle charging station.

In some embodiments, a plurality of dwelling current transformers is used to measure the auxiliary power lines of each dwelling to obtain a current consumption of the dwelling for each dwelling, and the measured current consumption of the dwelling for each dwelling is transmitted to the server. The server determines whether the current consumption of the dwelling for a specific dwelling is greater than a dwelling threshold value. When the current consumption of the dwelling for the specific dwelling is greater than the dwelling threshold value, the server executes a specific energy management scheme for the electric vehicle charging station corresponding to the specific dwelling, wherein the specific energy management scheme controls the charging operation of the electric vehicle charging station corresponding to the specific dwelling via the network.

In some embodiments, the server executes the at least one energy management scheme based on the current consumption of the dwelling for each dwelling and the current consumption of the community for the community.

In some embodiments, during the execution of the specific energy management scheme, the server transmits a first notification signal to a specific mobile device corresponding to the specific dwelling to notify a user of the specific dwelling that the specific dwelling is executing the specific energy management scheme for controlling the power consumption of the specific dwelling. During the execution of the energy management scheme, the server transmits a second notification signal to a community terminal corresponding to the community to notify a manager of the community that the community is executing the energy management scheme for controlling the power consumption of the community.

Methods of electric vehicle charging management for community with energy monitoring may take the form of a program code embodied in a tangible media. When the program code is loaded into and executed by a machine, the machine becomes an apparatus for practicing the disclosed method.

### BRIEF DESCRIPTION OF THE DRAWINGS

The invention will become more fully understood by referring to the following detailed description with reference to the accompanying drawings, wherein:

FIG. 1 is a schematic diagram illustrating an embodiment of a system of electric vehicle charging management for community with energy monitoring of the invention;

FIG. 2 is a schematic diagram illustrating an embodiment of an electric vehicle charging station of the invention;

FIG. 3 is a schematic diagram illustrating an embodiment of a server of the invention;

FIG. 4 is a flowchart of an embodiment of a method of electric vehicle charging management for community with energy monitoring of the invention;

FIG. 5 is a flowchart of an embodiment of a method of determining that a current consumption of the community meets a predetermined condition of the community of the invention;

FIG. 6 is a flowchart of another embodiment of a method of determining that a current consumption of the community meets a predetermined condition of the community of the invention;

FIG. 7 is a flowchart of another embodiment of a method of electric vehicle charging management for community with energy monitoring of the invention;

FIG. 8 is a flowchart of an embodiment of a method of executing an energy management scheme of the invention;

FIG. 9 is a flowchart of another embodiment of a method of executing an energy management scheme of the invention; and

FIG. 10 is a flowchart of another embodiment of a method of executing an energy management scheme of the invention.

### DETAILED DESCRIPTION OF THE INVENTION

The following description is of the best-contemplated mode of carrying out the invention. This description is made for the purpose of illustrating the general principles of the invention and should not be taken in a limiting sense. It should be understood that the embodiments may be realized in software, hardware, firmware, or any combination thereof.

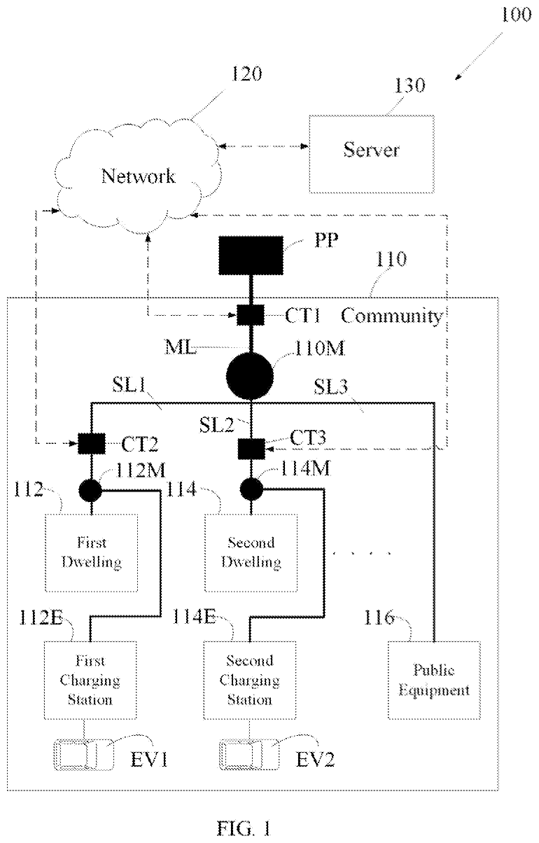

FIG. 1 is a schematic diagram illustrating an embodiment of a system of electric vehicle charging management for community with energy monitoring of the invention. The system of electric vehicle charging management for community with energy monitoring 100 can be used in a community 110 with a plurality of dwellings, such as a first dwelling 112 and a second dwelling 114. It is noted that, the community 110 has a power limitation. As shown in FIG. 1, the system of electric vehicle charging management for community with energy monitoring 100 comprises a plurality of electric vehicle charging stations, such as a first charging station 112E and a second charging station 114E, a public equipment 116, and a server 130 respectively connected with the first charging station 112E and the second charging station 114E via a network 120. Each charging station corresponds to a dwelling. For example, the first charging station 112E corresponds to the first dwelling 112 and shares the power supply of the first dwelling 112. The second charging station 114E corresponds to the second dwelling 114 and shares the power supply of the second dwelling 114. The respective charging stations can provide electric vehicles (EV1, EV2) of electric vehicle users for charging operations. It is noted that, the community 110 has a main power line ML, which is connected to a power supply terminal PP, such as a power plant or its substation, to obtain power. In the community 110, the main power line ML can be tapped into a plurality of auxiliary power lines to provide electricity for each of the dwellings in the community 110. For example, an auxiliary power line SL1 can provide power for the first dwelling 112 to use. An auxiliary power line SL2 can provide power for the second dwelling 114 to use. An auxiliary power line SL3 can provide power for the public equipment 116 to use. It is noted that, an electricity meter can be installed on the main power line of the community 110 and the auxiliary power lines of individual dwellings respectively to measure the power usage. As shown in FIG. 1, a community electricity meter 110M can be provided on the main power line ML, a dwelling electricity meter 112M can be provided on the auxiliary power line SL1, and a dwelling electricity meter 114M can be provided on the auxiliary power line SL2. In this embodiment, the main power line ML, the auxiliary power line SL1, and the auxiliary power line SL2 can be respectively provided with a community current transformer CT1, a dwelling current transformer CT2, and a dwelling current transformer CT3 for detecting the current in the respective lines. It should be noted that the community transformer CT1, the dwelling transformer CT2, and the dwelling transformer CT3 can further be connected to the server 130 through the network 120.

In some embodiments, the network 120 may be a wired network, a telecommunication network, and a wireless network, such as a Wi-Fi network. The server 130 can respectively receive various data from the first charging station 112E and the second charging station 114E, and transmit related signals to the first charging station 112E and the second charging station 114E. The first charging station 112E and the second charging station 114E can perform related operations according to the signals received from the server 130. For example, when the electric vehicle EV1 is coupled to the first charging station 112E through a charging gun of the first charging station 112E for a charging operation, the first charging station 112E can continuously transmit charging information corresponding the charging operation of the electric vehicle EV1 via the network 120, and the server 130 can receive the charging information of the corresponding charging operation from the first charging station 112E via the network 120. Similarly, when the electric vehicle EV2 is coupled to the second charging station 114E through a charging gun of the second charging station 114E to perform a charging operation, the second charging station 114E can continuously transmit the charging information corresponding the charging operation of the electric vehicle EV2 via the network 120, and the server 130 can receive the charging information of the corresponding charging operation from the second charging station 114E via the network 120. In some embodiments, the charging information may include at least a charging start time, a charging period, an output power, and/or related information indicating whether a load adjustment operation is being performed. The server 130 can know the usage status of the corresponding electric vehicle charging station according to the charging information. In addition, the server 130 may receive relevant data detected by the community current transformer CT1, the dwelling current transformer CT2, and/or the dwelling current transformer CT3 through the network 120, and perform related management operations according to the received data.

It is noted that the user can connect the electric vehicle EV1 and the first charging station 112E to each other, such as inserting a charging gun into the charging port of the electric vehicle to send a charging request corresponding to the first charging station 112E to use the first charging station 112E. The first charging station 112E performs a charging operation for the electric vehicle EV1. Similarly, the user can connect the electric vehicle EV2 and the second charging station 114E to each other, such as inserting a charging gun into the charging port of the electric vehicle to send a charging request corresponding to the second charging station 114E to use the second charging station 114E. It is understood that, in some embodiments, the server 130 may directly or indirectly receive a charging request from a mobile device (not shown in FIG. 1) of the owner of the electric vehicle EV1, and generate a charging authorization command based on the charging request and transmit it to the first charging station 112E via the network 120, so that the first charging station 112E outputs power to the electric vehicle EV1, such as an electric scooter or an electric car, which is electrically connected to it, or prohibits the first charging station 112E from outputting power to the electric vehicle EV1. It is reminded that, in some embodiments, the charging request may be accompanied by an identity authentication and/or a payment mechanism, and the charging authorization command will only be generated after the identity authentication and/or payment mechanism is completed. In some embodiments, the user of the electric vehicle EV1 can use his/her mobile device to download and install an application to generate a charging request through the user interface of the application. In some embodiments, the user can scan a Quick Response Code (QR code) on the first charging station 112E through the scanning function of the application to generate the above-mentioned charging request, thereby starting a charging operation. In some embodiments, the user can select a specific charging station through the application and execute an activation function to generate the above-mentioned charging request, thereby starting a charging operation. It is understood that, in some embodiments, the owner of the electric vehicle EV1 can use an RFID card to approach an induction area (not shown in FIG. 1) on the first charging station 112E to generate a corresponding charging request, and sent it to the server 130 via the network 120. It is reminded that, in some embodiments, each user can have an RFID card.

It is noted that, the device corresponding to the owner of the electric vehicle can be any electronic device capable of Internet access, such as mobile devices, such as mobile phones, smart phones, personal digital assistants, global positioning systems, and notebook computers. In some embodiments, the mobile device can receive status information and notifications of the corresponding charging operation from the cloud management server 130 via the network 120. In some embodiments, the status information and notification may include notifying that the electric vehicle has stopped charging, notifying that the vehicle needed to be moved, and/or notifying that the charging gun of the electric vehicle charging device has been disconnected from the electric vehicle, and so on.

As mentioned above, the community 110 has a power limit. The server 130 can perform a load adjustment operation for the electric vehicle charging stations of the corresponding individual dwellings in the community 110 according to at least one energy management scheme. Specifically, the server 130 can generate an instruction and send the instruction to the respective charging station (112E, 114E) via the network 120 to control the charging station to output power for charging with a specified power parameter, such as a specified amperage, during a specific period of time to the electric vehicle connected to the station, or to prohibit the charging station from outputting power to the electric vehicle. It is noted that, in some embodiments, when the server 130 receives the charging requests from the charging stations, a charging scheduling operation may be performed for the charging requests. In some embodiments, the charging scheduling operation may be performed in conjunction with a time-of use (TOU) rate. For example, when the electric vehicle and the charging station are connected to each other, for example, after the charging gun is inserted into the charging port of the electric vehicle, the corresponding charging operation will not be executed immediately. The server will schedule the charging operation for the respective electric vehicles according to the TOU rate, the power limit of the charging field, and the electric vehicles that needs to be charged, determine an appropriate charging time point for each charging operation, and accordingly execute the respective charging operations with the lowest electricity cost.

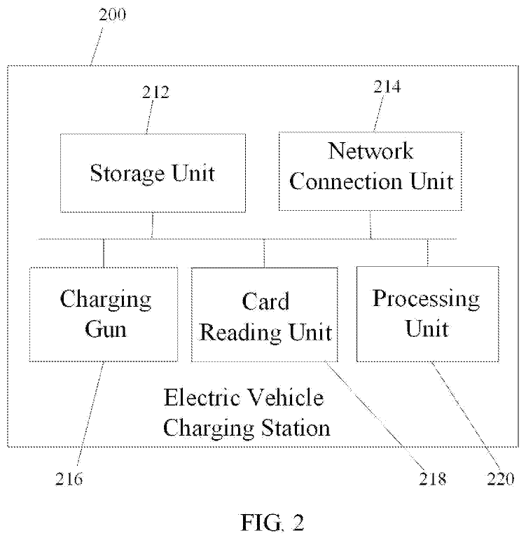

FIG. 2 is a schematic diagram illustrating an embodiment of an electric vehicle charging station of the invention. The electric vehicle charging station 200 shown in FIG. 2 can be applied to the first charging station 112E and the second charging station 114E in FIG. 1, which has processing and computing capabilities to perform charging management operations for the electric vehicle charging station. The electric vehicle charging station 200 has a network connection capability to receive, download or update various parameters and information required for charging management calculations.

The electric vehicle charging station 200 at least comprises a storage unit 212, a network connection unit 214, a charging gun 216, a card reading unit 218, and a processing unit 220. The storage unit 212 may be a memory or a database for storing and recording related data. The data may be related information such as charging station ID of the electric vehicle charging station and charging requests. It should be noted that the aforementioned information is only example, and the invention is not limited thereto. The network connection unit 214 can use a network, such as a wired network, a telecommunications network, and a wireless network, such as a Wi-Fi network, to receive, download, or update various parameters and information required for charging management operations. The charging gun 216 may include one or more charging connectors that meet the same charging interface specification or meet different charging interface specifications, and are electrically connected to the corresponding electric vehicle. The card reading unit 218 may be an RFID reading unit for sensing information of a physical card, such as RFID card. The information sensed from the RFID card may be a user identification code or a card identification code of the physical card.

The processing unit 220 can control the operations of related software and hardware in the electric vehicle charging station 200, and cooperate with the server 130 to execute the methods of the invention. Related details will be described later. It is noted that, in some embodiments, the processing unit 220 may be a general-purpose controller, a Micro-Control Unit, MCU, or a Digital Signal Processor, DSP, etc., to provide functions of data analysis, processing and calculation, but the present invention is not limited to this. In one embodiment, the processing unit 220 may use the network connection unit 214 to transmit the power state of the corresponding electric vehicle through a network for a cloud management server, such as the cloud server 130, for subsequent charging management. In another embodiment, the processing unit 220 can obtain the power parameter of a charging operation from the server 130, determine the output power according to the power parameter received from the server 130, and output the power to at least one electric vehicle through the charging gun 216 to perform the charging operation.

It is understood that, the electric vehicle charging station 200 has an upper power limit value and a lower power limit value. Specifically, the electric vehicle charging station 200 can use the upper power limit value as the power parameter at the highest to output power to the electric vehicle during a charging operation. On the other hand, the electric vehicle charging station 200 needs to use the lower power limit value as the power parameter at least to output power to the electric vehicle during a charging operation. It must be noted that, charging stations of different brands and models may have different upper power limit values for output power and lower power limit values for output power. The present invention is not limited to any value, and the value may be different for different charging stations.

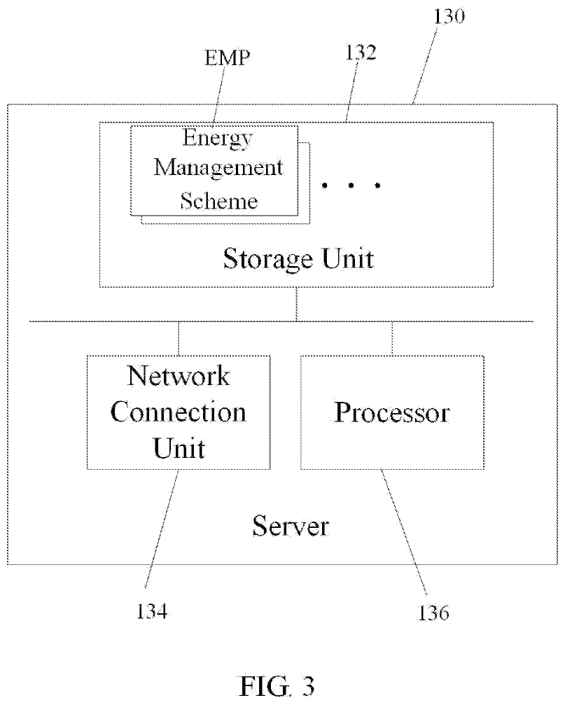

FIG. 3 is a schematic diagram illustrating an embodiment of a server of the invention. As shown in FIG. 3, the server 130 of the invention can be any processor-based electronic device, which comprises at least a storage unit 132, a network connection unit 134, and a processor 136. It is noted that, the server 130 can receive various data corresponding to a plurality of electric vehicle charging stations in a community. The server 130 can directly or indirectly receive a charging request from a mobile device, and after completing actions such as identity confirmation in response to the charging request, generate a charging authorization command and transmit it to the corresponding electric vehicle charging station via the network. In response to the charging authorization command, the electric vehicle charging station is allowed to output power to an electric vehicle (for example, an electric motorcycle or an electric vehicle, etc.) that is electrically connected to it, or prohibit the electric vehicle charging station from outputting power to the electric vehicle.

The storage unit 132 may be a memory, which can store and record related data, such as various data of the electric vehicle charging stations. It is noted that, the storage unit 132 may include at least one energy management scheme EMP. The energy management scheme EMP records a power distribution logic for controlling a charging operation of each electric vehicle charging station. It is reminded that, the power distribution logic is configured to determine the execution order of the individual charging requests (charging operations) of the corresponding charging stations, and the corresponding target power parameter value during the respective charging operations under the power limitation of the charging field. It should be noted that, in some embodiments, the storage unit 132 may include a time setting table for setting at least one peak period and one off-peak period, and a corresponding TOU rate. Through the network connection unit 134, the server 130 can be coupled to and communicates with the electric vehicle charging stations (112E, 114E) via the network 120, such as a wired network, a telecommunications network, and a wireless network, such as a Wi-Fi network, and transmits related data/signals/commands to different electric vehicle charging stations via the network 120 to control whether the electric vehicle charging stations output power, and specify power parameters for outputting power to electric vehicles. The processor 136 can control the operations of related software and hardware in the server 130, and execute the methods of the invention. The relevant details will be described later. It is reminded that, when the server has multiple energy management schemes EMPs, the processor 136 can select one of the energy management schemes EMPs, and execute a load adjustment operation for the charging field according to the selected energy management scheme EMP. It should be noted that, in some embodiments, the processor 136 may be a general-purpose controller, a microcontroller, or a digital signal controller, etc., for providing data analysis, processing and computing functions, but the present invention is not limited to this. It should be reminded that, as mentioned above, the server may execute a charging scheduling operation for the charging requests of the electric vehicle charging stations. In some embodiments, the charging scheduling operation can be performed with the TOU rate, so that all charging operations can be performed with the lowest electricity cost.

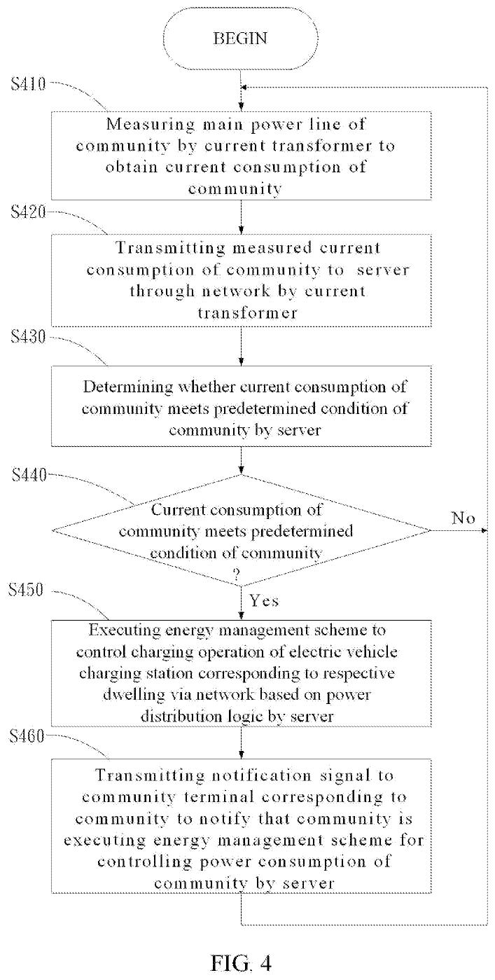

FIG. 4 is a flowchart of an embodiment of a method of electric vehicle charging management for community with energy monitoring of the invention. The method of electric vehicle charging management for community with energy monitoring of the invention is applicable to a community and the community has a power limit. The community comprises a plurality of dwellings, each of which has a corresponding electric vehicle charging station. The respective electric vehicle charging station in the community can be electrically coupled with a remote server via a network.

First, in step S410, a current transformer is first used to measure a main power line of the community to obtain a current consumption of the community. Note that the main power line can be tapped into multiple auxiliary power lines to provide electricity for each of the dwellings. In step S420, the current transformer transmits the measured current consumption of the community to the server via the network. In step S430, the server determines whether the current consumption of the community meets a predetermined condition of the community. It should be noted that each community can have its own set of conditions depending on its needs and circumstances. Related details will be described later. When the current consumption of the community does not meet the predetermined condition of the community (No for step S440), the process returns to step S410. When the current consumption of the community meets a predetermined condition of the community (Yes for step S440), in step S450, the server executes at least one energy management scheme. It is noted that the energy management scheme may record a power distribution logic, which is used to control the charging operation of the electric vehicle charging station corresponding to the respective dwelling via the network. It is reminded that, the power distribution logic is configured to determine the execution order of the individual charging requests (charging operations) of the corresponding charging stations, and the corresponding target power parameter value during the charging operation under the power limitation of the charging field. For example, when the current consumption of the community meets the predetermined condition of the community, a total number of the electric vehicle charging stations that need to perform charging operations and/or the output power of each electric vehicle charging station will be scaled down, so that the total current consumption of the community does not reach the predetermined condition. In some embodiments, in step S460, during the execution of the energy management scheme, the server transmits a notification signal to a community terminal corresponding to the community to notify a manager of the community that the community is executing the energy management scheme for controlling the power consumption of the community. It is noted that, in some embodiments, the server may stop the execution of the energy management scheme when the current consumption of the community does not meet the predetermined condition of the community.

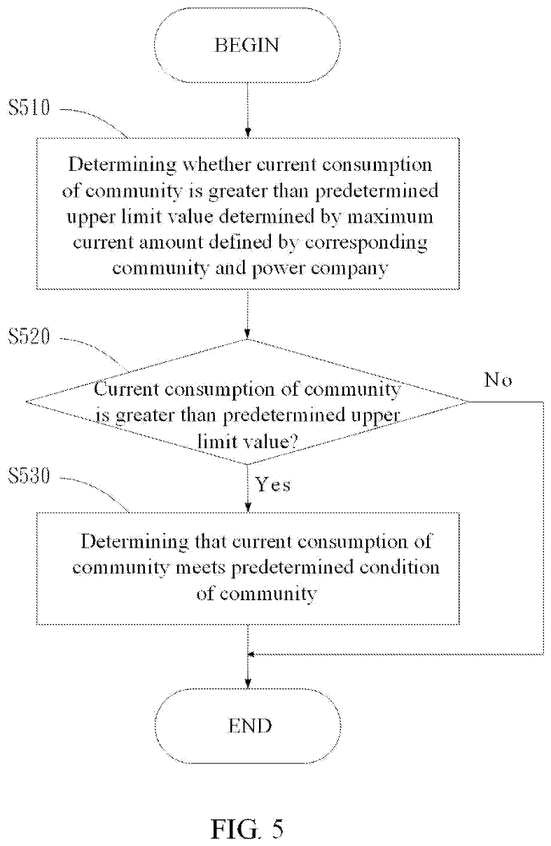

FIG. 5 is a flowchart of an embodiment of a method of determining that a current consumption of the community meets a predetermined condition of the community of the invention. First, in step S510, it is determined whether the current consumption of the community is greater than a predetermined upper limit value determined by a maximum current amount defined by the corresponding community and a power company. Note that, in some embodiments, the predetermined upper limit value may be 90% of the maximum current amount. When the current consumption of the community is not greater than the predetermined upper limit value (No in step S520), the process ends. In other words, it is determined that the current consumption of the community does not meet the predetermined condition of a community. When the current consumption of the community is greater than the predetermined upper limit value (Yes in step S520), in step S530, it is determined that the current consumption of the community meets the predetermined condition of the community. It should be noted that, in some embodiments, the predetermined upper limit value may include a plurality of sub-limit values, and when the current consumption of the community is greater than any one of the sub-limit values, the energy management scheme executed by the server is different. In other words, when current consumption of the community reaches different sub-limit values, the server can execute different energy management schemes.

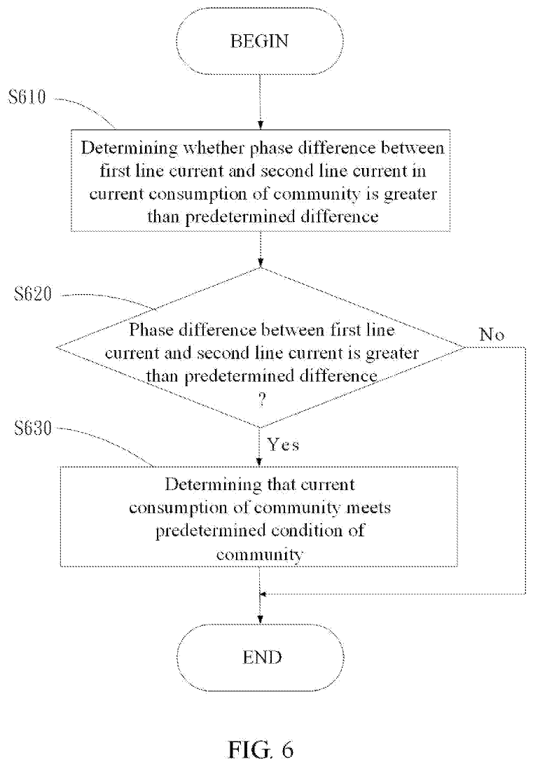

FIG. 6 is a flowchart of another embodiment of a method of determining that a current consumption of the community meets a predetermined condition of the community of the invention. First, in step S610, it is determined whether a phase difference between a first line current and a second line current in the current consumption of the community is greater than a predetermined difference. When the phase difference is not greater than the predetermined difference (No in step S620), the process ends. In other words, it is determined that the current consumption of the community does not meet the predetermined condition of the community. When the phase difference is greater than the predetermined difference (Yes in step S620), in step S630, it is determined that the current consumption of the community meets the predetermined condition of the community.

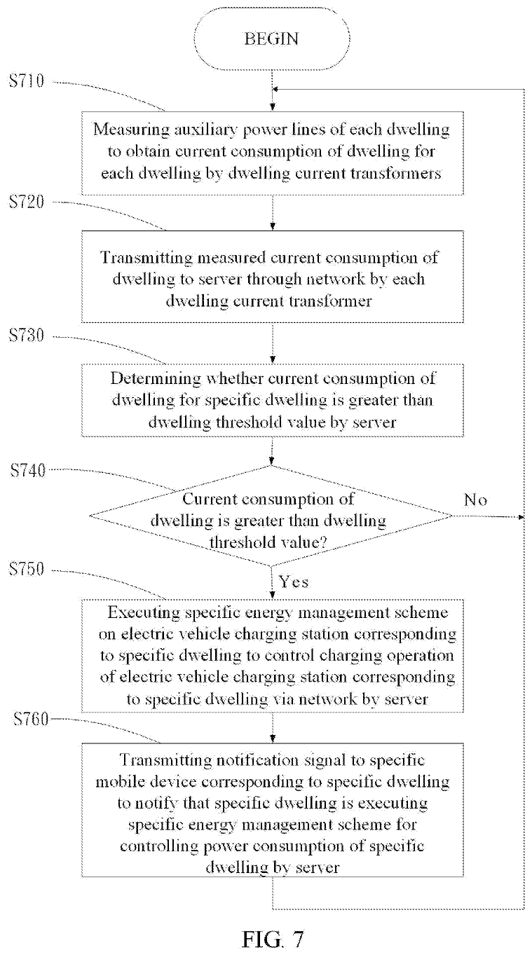

As mentioned above, in addition to the community current transformer in the community, each dwelling can also be provided with a corresponding dwelling current transformer to detect the power consumption of the individual dwelling. FIG. 7 is a flowchart of another embodiment of a method of electric vehicle charging management for community with energy monitoring of the invention. The method of electric vehicle charging management for community with energy monitoring of the invention is applicable to a community and the community has a power limit. The community comprises a plurality of dwellings, each of which has a corresponding electric vehicle charging station. The respective electric vehicle charging station in the community can be electrically coupled with a remote server via a network.

First, in step S710, a plurality of dwelling current transformers are used to measure the auxiliary power lines of each dwelling to obtain a current consumption of the dwelling for each dwelling, and in step S720, the measured current consumption of the dwelling for each dwelling is transmitted to the server through the network by respective dwelling current transformer. In step S730, the server determines whether the current consumption of the dwelling for a specific dwelling is greater than a dwelling threshold value. It is reminded that, in some embodiments, the dwelling threshold value may be set to 90%˜95% of the upper limit value of the power consumption of the dwelling. When the current consumption of the dwelling for the specific dwelling is not greater than the dwelling threshold value (No in step S740), the process returns to step S710. When the current consumption of the dwelling for the specific dwelling is greater than the dwelling threshold value (Yes in step S740), in step S750, the server executes a specific energy management scheme on the electric vehicle charging station corresponding to the specific dwelling, wherein the specific energy management scheme controls the charging operation of the electric vehicle charging station corresponding to the specific dwelling via the network. For example, when the current consumption of the dwelling for the specific dwelling is greater than the dwelling threshold value, the charging operation of the electric vehicle will be suspended/delayed, or the power output of the electric vehicle charging station will be reduced, so that the current consumption of the dwelling will not be greater than the dwelling threshold value. In some embodiments, in step S760, when the specific energy management scheme is being executed, the server transmits a notification signal to a specific mobile device corresponding to the specific dwelling to notify a user of the specific dwelling that the specific dwelling is executing the specific energy management scheme for controlling the power consumption of the specific dwelling. Thereafter, the process returns to step S710. It should be noted that, in some embodiments, the server may stop executing the specific energy management scheme when the current consumption of the dwelling for the specific dwelling is not greater than the dwelling threshold value. It should be noted that, in some embodiments, the embodiment of FIG. 7 can be performed independently. In some embodiments, the embodiment of FIG. 7 can be performed synchronously with the performance of the embodiment of FIG. 4.

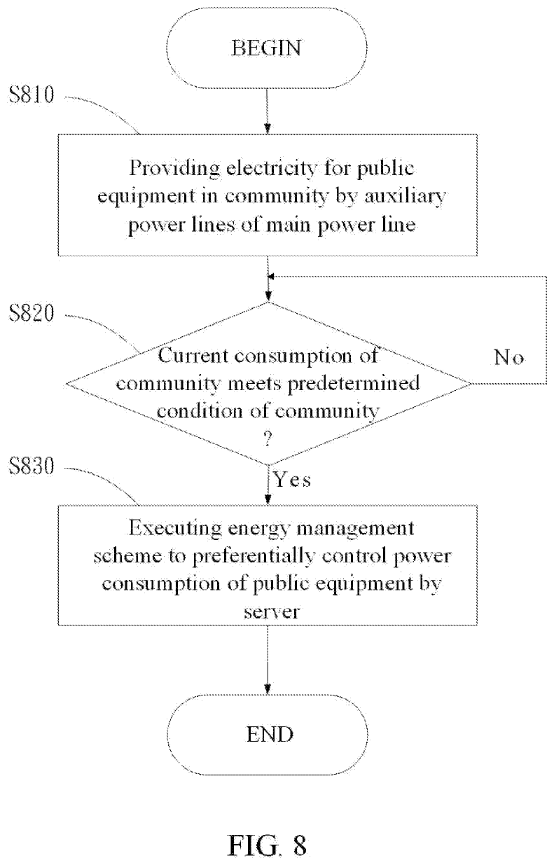

FIG. 8 is a flowchart of an embodiment of a method of executing an energy management scheme of the invention. First, in step S810, at least one of the auxiliary power lines of the main power line is used to provide electricity for at least one public equipment in the community. Next, in step S820, the server determines whether the current consumption of the community meets the predetermined condition of the community. When the current consumption of the community does not meet the predetermined condition of the community (No in step S820), the determination in step S820 is continued. When the current consumption of the community meets the predetermined condition of the community (Yes in step S820), in step S830, the energy management scheme executed by the server preferentially controls the power consumption of the at least one public equipment. For example, when the current consumption of the community meets the predetermined condition of the community, the server will give priority to control the power consumption of the public equipment in the community, such as lobby air conditioners and elevators. It is noted that, in this case, the public equipment can be connected to a server or a community energy management platform to receive management instructions from the corresponding server.

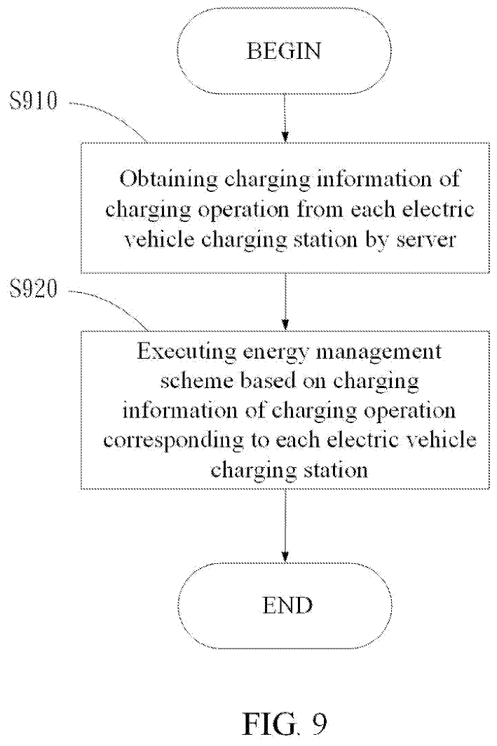

FIG. 9 is a flowchart of another embodiment of a method of executing an energy management scheme of the invention. First, in step S910, the server obtains charging information of a charging operation from each electric vehicle charging station. In some embodiments, the charging information may include a charging start time for the charging operation, a charging amount, or a remaining battery amount corresponding to an electric vehicle. In step S920, the server executes the at least one energy management scheme based on the charging information of the charging operation corresponding to each electric vehicle charging station.

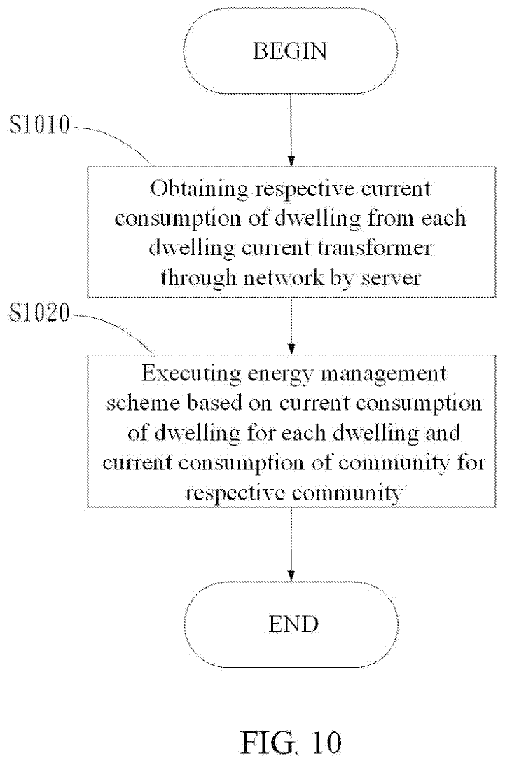

FIG. 10 is a flowchart of another embodiment of a method of executing an energy management scheme of the invention. First, in step S1010, the server obtains respective current consumption of the dwelling from the dwelling current transformer of each dwelling through the network. Then, in step S1020, the server executes the at least one energy management scheme based on the current consumption of the dwelling for each dwelling and the current consumption of the community for the community.

It should be reminded that the execution methods of the energy management schemes are disclosed in the foregoing embodiments, however, the present invention is not limited thereto. Any mechanism that can control and manage the energy of the electric vehicle charging station can be applied to the present application. Therefore, through the methods and systems of electric vehicle charging management for community with energy monitoring of the present invention, the overall power consumption of the community can be monitored, so as to provide charging operations for electric vehicles while maintaining the balance of power supply in the community, and at the same time ensuring the safety of power consumption in the community.

Methods of electric vehicle charging management for community with energy monitoring, may take the form of a program code (i.e., executable instructions) embodied in tangible media, such as floppy diskettes, CD-ROMS, hard drives, or any other machine-readable storage medium, wherein, when the program code is loaded into and executed by a machine, such as a computer, the machine thereby becomes an apparatus for executing the methods. The methods may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for executing the disclosed methods. When implemented on a general-purpose processor, the program code combines with the processor to provide a unique apparatus that operates analogously to application specific logic circuits.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalent.

What is claimed is:

1. A method of electric vehicle charging management for community with energy monitoring, which is applicable to a community including a plurality of dwellings, and each dwelling has an electric vehicle charging station connected to a server through a network, comprising:
measuring a main power line of the community to obtain a current consumption of the community by a current transformer, wherein the main power line is tapped into a plurality of auxiliary power lines to provide electricity for each of the dwellings;
transmitting the measured current consumption of the community to the server through the network by the current transformer;
determining whether the current consumption of the community meets a predetermined condition of the community by the server; and
executing at least one energy management scheme by the server when the current consumption of the community meets the predetermined condition of the community,
wherein the energy management scheme records a power distribution logic, which is used to control the charging operation of the electric vehicle charging station corresponding to the respective dwelling via the network.

2. The method of claim 1, wherein the server further determines whether the current consumption of the community meets the predetermined condition of the community by determining whether the current consumption of the community is greater than a predetermined upper limit value determined by a maximum current amount defined by the community and a power company, and determining that the current consumption of the community meets the predetermined condition of the community when the current consumption of the community is greater than the predetermined upper limit value.

3. The method of claim 2, wherein the predetermined upper limit value comprises a plurality of sub-limit values and when the current consumption of the community is greater than any of the sub-limit values, the energy management scheme executed by the server is different.

4. The method of claim 1, wherein the server further determines whether the current consumption of the community meets the predetermined condition of the community by determining whether a phase difference between a first line current and a second line current within the current consumption of the community is greater than a predetermined difference, and determining that the current consumption of the community meets the predetermined condition of the community when the phase difference is greater than the predetermined difference.

5. The method of claim 1, further comprising:
using at least one of the auxiliary power lines of the main power line to provide electricity for at least one public equipment in the community; and
executing the at least one energy management scheme by the server to preferentially control the power consumption of the at least one public equipment when the current consumption of the community meets the predetermined condition of the community.

6. The method of claim 1, further comprising:
obtaining charging information of a charging operation from each electric vehicle charging station by the server, wherein the charging information includes a charging start time for the charging operation, a charging amount, or a remaining battery amount corresponding to an electric vehicle; and
executing the at least one energy management scheme based on the charging information of the charging operation corresponding to each electric vehicle charging station by the server.

7. The method of claim 1, further comprising:
measuring the auxiliary power line of each dwelling to obtain a current consumption of the dwelling for each dwelling by a plurality of dwelling current transformers;
transmitting the measured current consumption of the dwelling to the server through the network by each dwelling current transformer;
determining whether the current consumption of the dwelling for a specific dwelling is greater than a dwelling threshold value by the server; and
executing a specific energy management scheme for the electric vehicle charging station corresponding to the specific dwelling by the server when the current consumption of the dwelling for the specific dwelling is greater than the dwelling threshold value,
wherein the specific energy management scheme controls the charging operation of the electric vehicle charging station corresponding to the specific dwelling via the network.

8. The method of claim 7, further comprising a step of executing the at least one energy management scheme based on the current consumption of the dwelling for each dwelling and the current consumption of the community for the community by the server.

9. The method of claim 1, further comprising:
transmitting a first notification signal to a specific mobile device corresponding to the specific dwelling to notify a user of the specific dwelling that the specific dwelling is executing the specific energy management scheme for controlling the power consumption of the specific dwelling by the server during the execution of the specific energy management scheme; and
transmits a second notification signal to a community terminal corresponding to the community to notify a manager of the community that the community is executing the energy management scheme for controlling the power consumption of the community by the server during the execution of the energy management scheme.

10. A system of electric vehicle charging management for community with energy monitoring for use in a community including a plurality of dwellings, comprising:
a plurality of electric vehicle charging stations, each corresponding to one of dwellings and having a network connecting capability;
a current transformer measuring a main power line of the community to obtain a current consumption of the community and transmitting the measured current consumption of the community to the server through a network, wherein the main power line is tapped into a plurality of auxiliary power lines to provide electricity for each of the dwellings; and
a server connected to each of the electric vehicle charging stations through the network, receiving the current consumption of the community for the community from the current transformer through the network, determining whether the current consumption of the community meets a predetermined condition of the community, and executing at least one energy management scheme when the current consumption of the community meets the predetermined condition of the community, wherein the energy management scheme records a power distribution logic, which is used to control the charging operation of the electric vehicle charging station corresponding to the respective dwelling through the network.

11. The system of claim 10, wherein the server further determines whether the current consumption of the community meets the predetermined condition of the community by determining whether the current consumption of the community is greater than a predetermined upper limit value determined by a maximum current amount defined by the community and a power company, and determining that the current consumption of the community meets the predetermined condition of the community when the current consumption of the community is greater than the predetermined upper limit value.

12. The system of claim 11, wherein the predetermined upper limit value comprises a plurality of sub-limit values and when the current consumption of the community is greater than any of the sub-limit values, the energy management scheme executed by the server is different.

13. The system of claim 10, wherein the server further determines whether the current consumption of the community meets the predetermined condition of the community by determining whether a phase difference between a first line current and a second line current within the current consumption of the community is greater than a predetermined difference, and determining that the current consumption of the community meets the predetermined condition of the community when the phase difference is greater than the predetermined difference.

14. The system of claim 10, wherein at least one of the auxiliary power lines of the main power line is further used to provide electricity for at least one public equipment in the community, and the server further executes the at least one energy management scheme to preferentially control the power consumption of the at least one public equipment when the current consumption of the community meets the predetermined condition of the community.

15. The system of claim 10, wherein the server further obtains charging information of a charging operation from each electric vehicle charging station, wherein the charging information includes a charging start time for the charging operation, a charging amount, or a remaining battery amount corresponding to an electric vehicle, and executes the at least one energy management scheme based on the charging information of the charging operation corresponding to each electric vehicle charging station.

16. The system of claim 10, further comprising a plurality of dwelling current transformers for measuring the auxiliary power line of each dwelling to obtain a current consumption of the dwelling for each dwelling, wherein each dwelling current transformer transmits respective measured current consumption of the dwelling to the server through the network, and the server further determines whether the current consumption of the dwelling for a specific dwelling is greater than a dwelling threshold value and executes a specific energy management scheme for the electric vehicle charging station corresponding to the specific dwelling when the current consumption of the dwelling for the specific dwelling is greater than the dwelling threshold value, wherein the specific energy management scheme controls the charging operation of the electric vehicle charging station corresponding to the specific dwelling via the network.

17. The system of claim 16, wherein the server further executes the at least one energy management scheme based on the current consumption of the dwelling for each dwelling and the current consumption of the community for the community.

18. The system of claim 10, wherein the server further transmits a first notification signal to a specific mobile device corresponding to the specific dwelling to notify a user of the specific dwelling that the specific dwelling is executing the specific energy management scheme for controlling the power consumption of the specific dwelling during the execution of the specific energy management scheme, and the server further transmits a second notification signal to a community terminal corresponding to the community to notify a manager of the community that the community is executing the energy management scheme for controlling the power consumption of the community during the execution of the energy management scheme.

19. A machine-readable storage medium comprising a computer program, which, when executed, causes a device to perform a method of electric vehicle charging management for community with energy monitoring, which is applicable to a community including a plurality of dwellings, and each dwelling has an electric vehicle charging station connected to a server through a network, wherein the method comprises:
measuring a main power line of the community to obtain a current consumption of the community by a current transformer, wherein the main power line is tapped into a plurality of auxiliary power lines to provide electricity for each of the dwellings;
transmitting the measured current consumption of the community to the server through the network by the current transformer;
determining whether the current consumption of the community meets a predetermined condition of the community by the server; and
executing at least one energy management scheme by the server when the current consumption of the community meets the predetermined condition of the community,
wherein the energy management scheme records a power distribution logic, which is used to control the charging operation of the electric vehicle charging station corresponding to the respective dwelling via the network.
